(19) United States
(12) Patent Application Publication
(10) Pub. No.: US 2002/0076907 A1
(43) Pub. Date: Jun. 20, 2002

(54) Transistor having a silicided gate and method of forming

(76) Inventor: Mark S. Rodder, University Park, TX (US)

Correspondence Address: TEXAS INSTRUMENTS INCORPORATED, P O BOX 655474, M/S 3999, DALLAS, TX, 75265

(21) Appl. No.: 09/737,396

(22) Filed: Dec. 14, 2000

Related U.S. Application Data
(60) Provisional application No. 60/174,968, filed on Jan. 6, 2000.

(51) Int. Cl. H01L 21/4763; H01L 21/3205

(52) U.S. Cl. 438/586; 438/592

(57) ABSTRACT

Transistor 10 is formed having a silicide body 36 formed on an outer surface of a gate conductor 18. Transistor 10 further comprises a source region 14 and a drain region 16 formed in an outer surface of a semiconductor layer 12. The silicide body 36 is formed using a mask oxide layer 30 such that the silicide layer silicide body 36 is formed proximate a gate conductor 18 but. The source region 14 and drain region 16 are covered by mask oxide layer 30 during the formation of silicide body 36 in order to prevent the formation of excessive silicide regions proximate the outer surface of semiconductor layer 12.

### TECHNICAL FIELD OF THE INVENTION

This invention relates in general to the field of electronic devices and more specifically to an improved transistor having a silicided gate and method for forming the same.

### BACKGROUND OF THE INVENTION

The performance of modern semiconductor devices is often limited by the sheet resistance of various structures within the devices. For example, a field effect transistor having a very narrow gate line width can suffer if the sheet resistance of the gate material is not sufficient to allow for the efficient operation of the device. One technique used to reduce the sheet resistance of portions of semiconductor devices is the process of self-aligned silicidation commonly referred to as salicidation. Field effect transistor devices typically utilize salicidation for the gate and source and drain regions of the device. If salicidation is used on the source and drain regions as well as the gate the device can suffer from high diode leakage in the active regions. This occurs when the silicide depth is deep compared to the source drain junction depth. This problem commonly occurs due to a deterioration of the isolation oxide on the perimeters of the active region adjacent to the edges of the source and drain regions. A phenomenon known as oxide pullback results in the exposure of undoped semiconductor material between the isolation oxide and the source and drain regions. If the source and drain regions are then subjected to a salicidation process, the salicidation of these exposed regions can create a high leakage area where the low resistance silicide is in direct contact with the bulk semiconductor material underlying the active region of the device.

One technique for eliminating this problem is disclosed in U.S. Pat. No. 4,587,718 issued to Haken et al. This technique involves the construction of a hybrid gate stack that includes layers of polycrystalline silicon and silicon nitride. A thermal oxide is then grown over the transistor prior to the formation of a silicide layer adjacent the gate. Using the techniques described in the Haken patent, a silicide layer is only formed over the gate and not over the source and drain regions. While this solves the problems associated with the formation of silicide in the source and drain regions, the Haken technique requires the formation of a much more complex gate stack and the growth of a thermal oxide on previously doped source drain regions. Both of these steps in the device creation can be expensive and problematic.

### SUMMARY OF THE INVENTION

Accordingly, a need has arisen for a new method of forming a transistor having a silicided gate that addresses problems associated with prior art devices and methods of formation.

In accordance with teachings of the present invention, a method of forming a transistor is disclosed that substantially eliminates problems associated with prior art methods of construction.

According to one embodiment of the present invention, a method of forming a transistor is disclosed that comprises the steps of forming source and drain regions proximate an outer surface of a semiconductor layer. A gate body is then formed proximate the outer surface of the semiconductor layer and separated from the outer surface of the semiconductor layer by a gate insulator layer. An insulative layer is then deposited covering the outer surface and the gate body. The insulator layer is then selectively etched to expose the outer surface of the gate body. A silicide layer is then formed on the exposed surface of the gate body.

An important technical advantage of the present invention inheres in the fact that it allows for the selective creation of a self-aligned silicide layer on the outer surface of the gate body without the exposure of the source and drain regions of the device.

### BRIEF DESCRIPTION OF THE DRAWINGS

A more complete understanding of the present invention may be acquired by referring to the accompanying figures in which like reference numbers indicate like features and wherein:

FIGS. 1A-1E are a sequence of cross sectional elevational schematic diagrams illustrating the formation of a device constructed according to the teachings of the present invention.

### DETAILED DESCRIPTION OF THE INVENTION

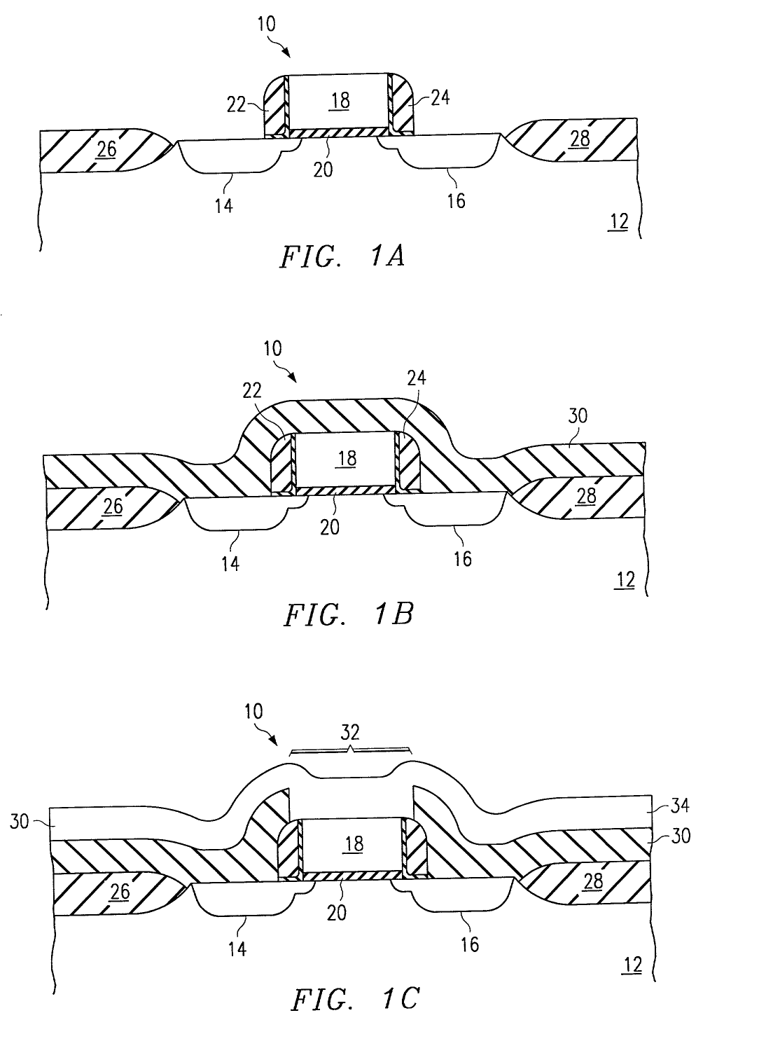

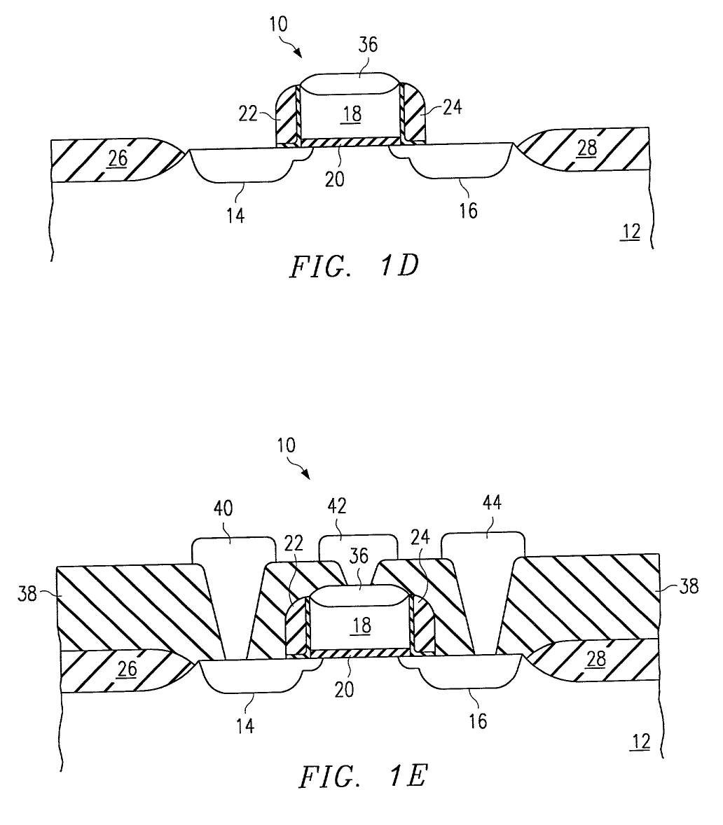

FIG. 1A is a cross sectional elevational diagram of a partially formed field effect transistor indicated generally at 10. Transistor 10 is formed on the outer surface of a semiconductor layer 12 which may comprise for example silicon or gallium arsenide. Transistor 10 comprises a source region 14 and a drain region 16. Source and drain regions 14 and 16 may be formed through the implantation of an impurity such as arsenic at an energy on the order of 40 KeV at a dosage on the order of 1E15 cm⁻² or phosphorous at an energy on the order of 30 KEV and a dosage on the order of 1E13 cm⁻². These implantation together with subsequent annealing steps will result in the depth of source and drain regions 14 and 16 to be on the order of 1500 angstroms from the outer surface of semiconductor layer 12. In addition, source and drain regions 14 and 16 may comprise small source and drain extensions to the depth of on the order of 500 angstroms as shown in FIG. 1A created using conventional lower dose implantation steps.

Transistor 10 also comprises a gate conductor 18 which is separated from the outer surface of layer 12 by a gate insulator layer 20. Gate insulator layer may comprise a layer of silicon dioxide or other suitable insulative materials on the order of 30 angstroms in thickness. Gate conductor 18 may comprise a layer of polycrystalline silicon on the order of 2,500 angstroms in thickness and on the order of 0.15 microns in width. Gate conductor 18 may be rendered conductive by doping it with an impurity such as phosphorous at an energy on the order of 50 KeV and a dosage on the order of 2E15 cm⁻². Transistor 10 also comprises sidewall spacer bodies 22 and 24 which each comprise a layer of silicon dioxide on the order of 150 angstroms in thickness and a layer of silicon nitride on the order of 1,000 angstroms in thickness. Spacer bodies 22 and 24 are constructed according to conventional techniques through the formation of a composite layer of oxide and nitride and then the anisotropic etching of those layers resulting in the formation of bodies 22 and 24 as shown in FIG. 1A.

Transistor 10 is disposed in an active region of the outer surface of semiconductor layer 12 which is defined at its perimeters by isolation oxide layers 26 and 28. Oxide layers 26 and 28 may comprise for example silicon dioxide and are used to separate various devices formed on the outer surface of layer 12. As shown in FIG. 1A, isolation oxide layer 26 has degraded during the formation of transistor 10 so that a portion of the semiconductor layer 12 is exposed between layer 26 and source region 14. A similar portion of layer 12 is exposed between drain region 16 and isolation oxide layer 28. If, during the completion of transistor 10, a silicide layer were to be formed on source and drain regions 14 and 16, the silicide material might contact the exposed portions of the outer surface of layer 12. If this were to happen, transistor 10 might exhibit unsuitably high diode leakage because of the low resistance contact point between the silicide and the layer 12 on the outer edges of source region 14 and drain region 16. This degradation of the performance of transistor 10 is not desirable and, as such, the teachings of the present invention provide for a method for the formation of a silicide layer to reduce the sheet resistance of gate conductor 18 without the formation of silicide material near source region 14 or gate region or drain region 16. It should be understood that while isolation oxide layers 26 and 28 are shown to be shaped as typical Locos oxide formations, the teachings of the present invention are equally applicable to other methodologies of isolation such as trench isolation.

Referring to FIG. 1B, one embodiment of the method of the present invention is initiated through the formation of a mask oxide layer 30 covering the outer surfaces of isolation oxide layers 26 and 28, source and drain regions 14 and 16, sidewall insulator bodies 22 and 24, and gate conductor layer 18. Mask oxide layer 30 may comprise for example a layer of silicon dioxide which is deposited to a depth on the order of 1,500 angstroms.

Referring to FIG. 1C, an opening indicated generally at 32 is formed in the mask oxide layer 30 using suitable photolithographic and oxide etching techniques to expose the outer surface of gate conductor 18. In the alternative, due to the topography of the outer surface of device 10 transistor 10, the outer surface of gate conductor 18 may be exposed using a chemical mechanical polishing operation which would result in the exposure of the outer surface of gate conductor 18 while leaving the outer surfaces of the remainder of transistor 10 covered.

A layer of refractory metal 34 which may comprise, for example, cobalt or titanium is then deposited covering the outer surface of the remaining outer surface of layer 30 and the exposed outer surface of gate conductor 18. Layer 34 may be deposited to on the order of 50 to 100 angstroms in depth. The resulting structure is then heated to a temperature of 500° C. for a period of 0.5 minutes to react the metal within layer 34 with the polycrystalline silicon in gate conductor layer 18 to form a silicide body 36 which is shown in FIG. 1D. Silicide body 36 covers the outer surface of gate conductor 18 and serves to greatly reduce the sheet resistance of gate conductor layer 18. The structure shown in FIG. 1D is accomplished through the formation of silicide body 36 as discussed previously and the subsequent stripping of the unreacted metal within layer 34 and the stripping of the remainder of mask oxide layer 30.

Transistor 10 may then be completed through the deposition of a interlevel isolation layer 38 and the formation of a source contact 40 a gate contact 42 and a drain contact 44 as shown in FIG. 1E. Interlevel isolation layer 38 may comprise for example a relatively thick layer of deposited silicon dioxide. Contacts 40, 42 and 44 may comprise, for example, a suitable conductor such as aluminum which is deposited and etched using conventional techniques after the formation of openings within interlevel isolation layer 38.

Although the techniques of the present invention have been described with reference to the specific example shown in FIGS. 1A-1E, it should be understood that the structure disclosed is disclosed solely for purposes of teaching the advantage of the present invention and should not be construed to limit the scope of the present invention to this or any particular embodiment. For example, although the technique is shown in an embodiment where no silicide or other treatment of the outer surface of the source and drain regions is disclosed, it should be understood that thin silicide layers could be formed outwardly from the source and drain regions. The techniques of the present invention allow for the source and drain regions on the one hand and the gate region on the other hand to be processed independently. Accordingly, a thinner silicide layer could be formed on the outer surfaces of the source and drain regions which would not be problematic while a much thicker silicide layer could be formed on the outer surfaces of the gate conductor while the source and drain regions are covered using the techniques of the present invention. In this manner, the silicidation techniques can be used to their maximum effect to reduce the sheet resistance of the gate conductor and not provide for high leakage in the source and drain regions.

Although the present invention has been described in detail, it should be understood that various changes, alterations, substitutions and modifications may be made to the teachings described herein without departing from the spirit and scope of the invention which is solely defined by the appended claims.

What is claimed is:

1. A method for forming a transistor comprising:
forming source and drain regions proximate the outer surface of a semiconductor layer;
forming a gate conductor proximate the outer surface of the semiconductor layer between the source and drain regions and separated from the outer surface of the semiconductor layer by a gate insulator layer; and
forming a gate silicide body on the outer surface of the gate conductor layer by first covering the outer surfaces of the source and drain regions with a mask oxide layer.

2. The method of claim 1 and further comprising the steps of forming sidewall spacer bodies adjoining the gate conductor layer and the outer surface of the semiconductor layer.

3. The method of claim 1 wherein the step of forming a silicide body comprises the steps of forming an opening in the mask oxide layer and depositing a layer of refractory metal in the opening in the mask oxide layer.

4. The method of claim 3 wherein the refractory metal comprises titanium.

5. The method of claim 3 wherein the refractory metal comprises cobalt.

6. The method of claim 3 wherein the step of creating an opening in the mask oxide layer comprises the step of photolithographically patterning an outer surface of the mask oxide layer and etching the opening in the mask oxide layer.

7. The method of claim 3 wherein the step of forming an opening in the mask oxide layer comprises the step of polishing the outer surface of the mask oxide layer using chemical and mechanical processes until an opening is formed exposing the outer surface of the gate conductor body.

8. The method of claim 1 wherein the semiconductor layer comprises silicon, the gate conductor layer comprises polycrystalline silicon and the mask oxide layer comprises silicon dioxide.

9. The method of claim 1 and further comprising the step of forming a separate silicide body in contact with either or both of the source and drain regions in a separate step from the step used to form the gate silicide body.

10. A method for forming a transistor comprising:
forming source and drain regions proximate the outer surface of a semiconductor layer;
forming a gate conductor proximate the outer surface of the semiconductor layer between the source and drain regions and separated from the outer surface of the semiconductor layer by a gate insulator layer; and
forming a gate silicide body on the outer surface of the gate conductor layer by:
covering the outer surfaces of the source and drain regions with a mask oxide layer,
forming an opening in the mask oxide layer by photolithographically patterning an outer surface of the mask oxide layer and etching the opening in the mask oxide layer, and
depositing a layer of refractory metal in the opening in the mask oxide layer.

11. The method of claim 10 wherein the refractory metal comprises titanium.

12. The method of claim 10 wherein the refractory metal comprises cobalt.

13. The method of claim 10 wherein the semiconductor layer comprises silicon, the gate conductor layer comprises polycrystalline silicon and the mask oxide layer comprises silicon dioxide.

14. The method of claim 10 and further comprising the step of forming a separate silicide body in contact with either or both of the source and drain regions in a separate step from the step used to form the gate silicide body.

15. A transistor formed at an outer surface of a semiconductor layer, comprising:
source and drain regions proximate the outer surface of the semiconductor layer;
a gate conductor proximate the outer surface of the semiconductor layer between the source and drain regions and separated from the outer surface of the semiconductor layer by a gate insulator layer; and
a gate silicide body disposed on the outer surface of the gate conductor layer and formed by first covering the outer surfaces of the source and drain regions with a mask oxide layer.

16. The transistor of claim 15 and further comprising silicide bodies in contact with the source and drain regions and formed independently of the gate silicide body.
